(19) United States
(12) Patent Application Publication
(10) Pub. No.: US 2010/0046173 A1
(43) Pub. Date: Feb. 25, 2010

(54) Method and System for Adapting a Mobile Computing Device with a Grounded Metallic Housing

(76) Inventors: David Bellows, Wantagh, NY (US); Thomas Wulff, North Patchogue, NY (US)

Correspondence Address: MOTOROLA, INC., 1303 EAST ALGONQUIN ROAD, IL01/3RD, SCHAUMBURG, IL, 60196, US

(21) Appl. No.: 12/195,799

(22) Filed: Aug. 21, 2008

(51) Int. Cl. H05K 7/20

(52) U.S. Cl. 361/710; 361/711

(57) ABSTRACT

Devices and systems are for adapting a mobile computing device, such as a handheld radio frequency identification (“RFID”) reader, with a grounded metallic housing substrate without impacting the performance of the device. The device includes a heat generating component, and a heat sink in thermal contact with the heat generating component, the heat sink including at least one thermally conductive material. The system includes a mobile computing device including a heat generating component, and a heat sink in thermal contact with the heat generating component, the heat sink including at least one thermally conductive material.

### FIELD OF INVENTION

The present invention generally relates to systems and methods for adapting a mobile computing device, such as a handheld radio frequency identification (“RFID”) reader, with a grounded metallic housing substrate without impacting the performance of the device.

### BACKGROUND

Mobile computing devices, or mobile units (“MUs”), such as RFID readers, are used in a multitude of situations for both personal and business purposes. As the benefits of utilizing MUs expand rapidly across more industries, the features of these products expand at a corresponding pace. Accordingly, a demand exists for MUs to perform more complicated tasks in a quick, efficient and reliable manner.

Radio frequency identification (“RFID”) technology includes systems and methods for non-contact reading of targets (e.g., products, people, vehicles, livestock, etc.) in order to facilitate effective management of these targets within a business enterprise. Specifically, RFID technology allows for the automatic identification of targets, storing target location data, and remotely retrieving target data through the use of RFID tags, or transponders. The RFID tags are an improvement over standard bar codes since the tags may have read and write capabilities. Accordingly, the target data stored on RFID tags can be changed, updated, and/or locked. Due to the ability to track moving objects, RFID technology has established itself in a wide range of markets, including retail inventory tracking, manufacturing production chain, and automated vehicle identification systems. For example, through the use of RFID tags, a retail store can see how quickly the products leave the shelves and gather information on the customer buying the product.

Handheld RFID readers need to balance the physical characteristics of the device (e.g., size and weight) with overall performance and functionality of the device. In order to get a smaller and lighter device without compromising performance, the radio and antenna require a relatively significant amount of power. As a result, the temperature of the RFID reader tends to become hotter as much of this power is inefficiently wasted as emitted heat.

### SUMMARY OF THE INVENTION

The present invention generally relates to devices and systems for adapting a mobile computing device, such as a handheld radio frequency identification (“RFID”) reader, with a grounded metallic housing substrate without impacting the performance of the device. One exemplary device includes a heat generating component, and a heat sink in thermal contact with the heat generating component, the heat sink including at least one thermally conductive material. One exemplary system includes a mobile computing device including a heat generating component, and a heat sink in thermal contact with the heat generating component, the heat sink including at least one thermally conductive material. A further exemplary device includes at least one radio transmission means for transmitting and receiving data from at least one target over a radio frequency, and a heat transferring means in thermal contact with the at least one radio, the heat transferring means including at least one thermally conductive material.

### BRIEF DESCRIPTION OF THE DRAWINGS

FIG. 1 shows an exemplary embodiment of a system for adapting a mobile computing device, such as a handheld radio frequency identification (“RFID”) reader, with a heat sink without impacting the performance of the device according to the exemplary embodiments of the present invention.

FIG. 2 shows a further exemplary embodiment of a system for adapting a mobile computing device, such as an RFID reader, with a heat sink having cooling fins according to the exemplary embodiments of the present invention.

FIG. 3 shows a block diagram of a system for adapting a radio, such as an ultrahigh frequency (“UHF”) RFID radio, onto a general-purpose handheld mobile computing device according to the exemplary embodiments of the present invention.

### DETAILED DESCRIPTION

The exemplary embodiments of the present invention may be further understood with reference to the following description of exemplary embodiments and the related appended drawings, wherein like elements are provided with the same reference numerals. The exemplary embodiments of the present invention are related to systems and methods for adapting a mobile computing device, such as a handheld radio frequency identification (“RFID”) reader, with a grounded metallic housing substrate without impacting the performance of the device. Specifically, the present invention is related to a system and method for implementing a metal heat sink on a general-purpose handheld mobile computing device, or mobile unit (“MU”). As will be described in greater details below, a housing of the MU may act as the heat sink, wherein heat is drawn out from the MU.

It should be noted that while an exemplary embodiment of the MU may include a radio frequency identification (“RFID”) reader, alternative embodiments of the MU are not limited to RFID readers. For example, the MU may include a laser-based scanner, an image-based scanner, a personal digital assistant (“PDA”), a mobile telephone, a portable gaming console, a laptop, etc. Accordingly, various embodiments of the present invention will be described with reference to an exemplary MU. However, those skilled in the art will understand that the present invention may be implemented with any electrical and/or mechanical hand-operated device that can be attached to a modular accessory.

An antenna's performance may be directly linked to the amount of power supplied to the antenna. This is especially true for ultrahigh frequency (“UHF”) RFID antennas, which may require a relatively large amount of power from the MU. Conventional MUs, such as scanning devices, do not have a heat sink to draw heat from the device. As the amount of power required for operating radio antennas increases, the amount of thermal energy within the MU increases with it. Thus, a device's inability to extract the heat produced during operation may limit the power that is available to the antenna. However, the exemplary embodiments of the present invention allow an MU to accommodate an increase in power required by high-powered antennas without impacting the overall performance of the MU. Accordingly, the exemplary systems and method of the present invention address this issue. As will be described in greater detail below, the exemplary systems and methods implement a heat sink into the MU without compromising the performance of the MU and without limiting any features of the MU.

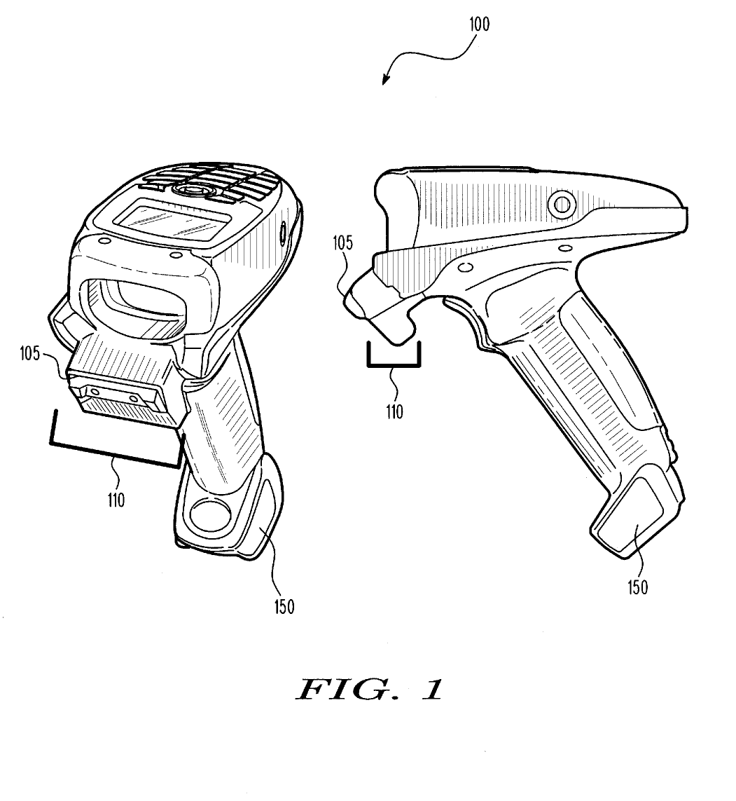

FIG. 1 shows an exemplary embodiment 100 of a system for adapting a mobile computing device, MU 150, such as a handheld radio frequency identification (“RFID”) reader, with a heat sink 110 without impacting the performance of the device according to the exemplary embodiments of the present invention. As described above, the MU 150 may be a general-purpose handheld computing device, such as a barcode scanner that also includes RFID reader functionality. Accordingly, the MU 150 may include a housing 105 for containing the internal electronic and mechanical components. Furthermore, the housing 105 of the MU 150 may include the heat sink 110. It should be noted that while the exemplary embodiment 100 illustrated in FIG. 1 shows the heat sink 110 as a separate component on the housing 105, alternative embodiments of the MU 150 may allow for the housing 105, itself, to serve as a heat sink. In addition, it should be noted that the heat sink 110 may be electrically connected to the system's ground (not shown).

According to the exemplary embodiments of the MU 150, the heat sink 110 may be described as a device that is attached to one or more electronic components (e.g., the components within the MU 150) in order to keep the components from overheating. Specifically, the heat sink 110 may be capable of absorbing and dissipating heat from within the MU 150 by using thermal contact. Thermal contact with the heat sink 110 may be via direct physical contact and/or radiant contact. Those skilled in the art would understand that heat sinks function by efficiently transferring thermal energy away from an object having a high temperature, such as the components (e.g., RFID radio component) of the MU 150, to a second object at a lower temperature with a much greater heat capacity, such as the heat sink 110. The transfer of thermal energy may bring the components into thermal equilibrium with the heat sink 110, thereby lowering the temperature of the components. Efficient function of a heat sink 110 may rely on rapid transfer of thermal energy from the first object to the heat sink 110.

Furthermore, as will be described in greater detail below, the heat sink 110 may be positioned either in a front end of the MU 150, near and/or around the RFID radio component of the MU 150. For example, the exemplary heat sink 110 may surround the RFID radio component to draw heat out from the MU 150. Since the RFID radio component may be positioned at the front end of the MU 150, locating the heat sink 110 at the front end may position the heat sink 110 for optimal performance (e.g., heat transferring performance). In another example, the housing 105 of the MU 150 may act as the exemplary heat sink. Regardless of the location and/or which component serves as the heat sink 110, the implementation of the heat sink 110 may balance any RF impact the metallic component has with the RFID antenna of the MU 150. In addition, the exemplary systems and methods may also take into consideration any inherent electrostatic discharge (“ESD”) entry points introduced to the MU 150 when adapting the MU 150 with the heat sink 110. Because the heat sink 110 is metal, it will be prone to receiving ESD hits from the environment. Since this heat sink 110 is thermally connected to hot internal electronics, an electrical path for ESD to travel to these electronics also exists. However, by electrically connecting the metal heat sink 110 to the MU 150 system's ground, the negative effects of ESD entering the MU 150 are mitigated.

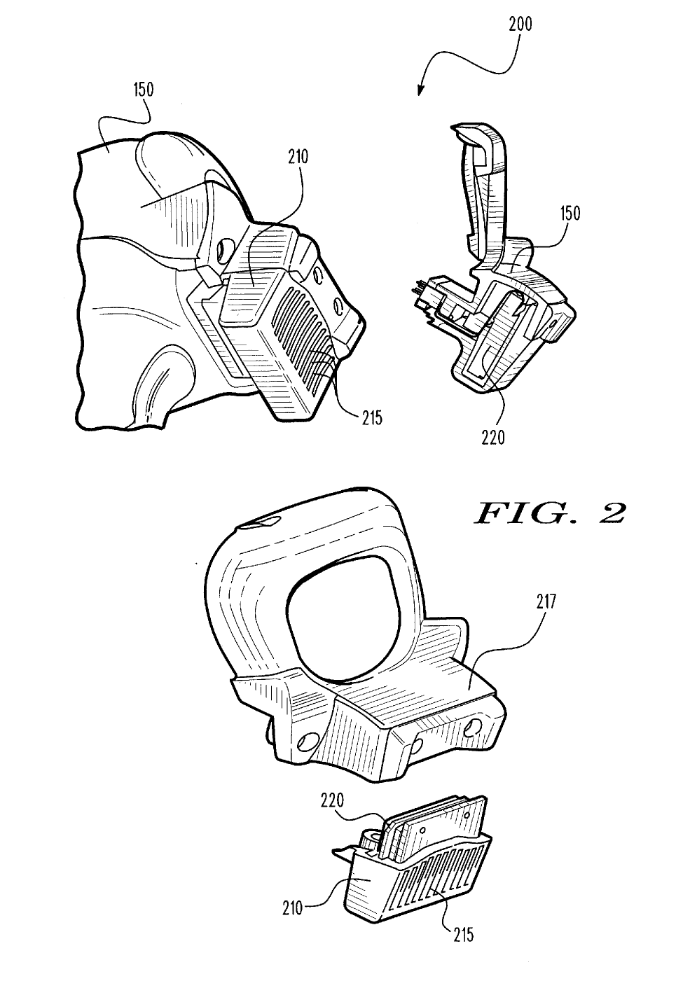

FIG. 2 shows a further exemplary embodiment 200 of a system for adapting a mobile computing device, MU 150, such as a handheld RFID reader, with a heat sink 210 having cooling fins 215 according to the exemplary embodiments of the present invention. Specifically, the heat sink 210 may be placed around an RFID radio component 220 within the MU 150. In other words, the heat sink 210 may be within thermal contact of the RFID radio component 220 through direct physical contact and/or radiant contact. The RFID radio component may be in communication with one or more RFID antennas, such as, for example, a UHF RFID antenna. As described above, the heat sink 210 may be electrically connected to system's ground.

Furthermore, the heat sink 210 may be attached to the MU 150 via a receiving component 217. It should be noted that the receiving component 217 may be molded onto the MU 150. Alternatively, the receiving component 217 may be detachably coupled to the MU 150.

According to the exemplary embodiment 200, the exemplary heat sink 210 may be composed of a thermally conductive material and may include a plurality of cooling fins 215. For instance, the heat sink 210 may be made from good thermal conductors such as, but limited to, copper alloys, aluminum alloys, silver alloys, etc. Accordingly, this allows the heat sink 210 to cool whatever it is in thermal contact with. Furthermore, it should be noted that the heat sink 210 may be made of any combination of thermally conductive materials (e.g., a thermal compound), such as by bonding copper with aluminum.

The high thermal conductivity of the metal combined with the added surface area of the cooling fins 215 may result in the rapid transfer of thermal energy to the area surrounding the housing 105 (e.g., the cooler air external to the MU 150). According to the exemplary embodiments of the present invention, the heat sink 210 may be designed to allow good thermal transfer from the heat source to the cooling fins 215. In one embodiment, thicker fins may be utilized to improve thermal conduction, while an alternative embodiment may utilize thinner cooling fins for increased surface area. Thus, a compromise between high surface area (e.g., many thinner cooling fins) and good thermal conduction (e.g., fewer thicker cooling fins) may be achieved. Furthermore, heat pipes (not shown) may be used to lead the heat from the heat source to the parts of the cooling fins 215 that may be further away from the heat source.

As described above, the exemplary embodiments of the systems and method may dispose the heat sink 210 (or metal housing 105) around the RFID radio component 220. It should be noted that the front end of the MU 150 may include an arrangement for receiving and/or transmitting data, such as a data capturing arrangement for collecting data from items such automatic identification items (e.g., barcode, image data, RFID tags, etc.). Accordingly, the front end of the MU 150 may be described as, but is not limited to, a data receiving end, a barcode scanning end (e.g., a scan exit window), etc.

In one exemplary embodiment of the present invention, the heat sink 210 may surround the RFID radio 220 on five sides, including the front end side, as illustrated in FIG. 2. Accordingly, the placement of the heat sink 210 within the MU 150 may create a gap between the radio 220 and the housing 105. In addition, a thermal interface material may fill this gap in order to help transfer any heat generated at the radio 220 out of the MU 150.

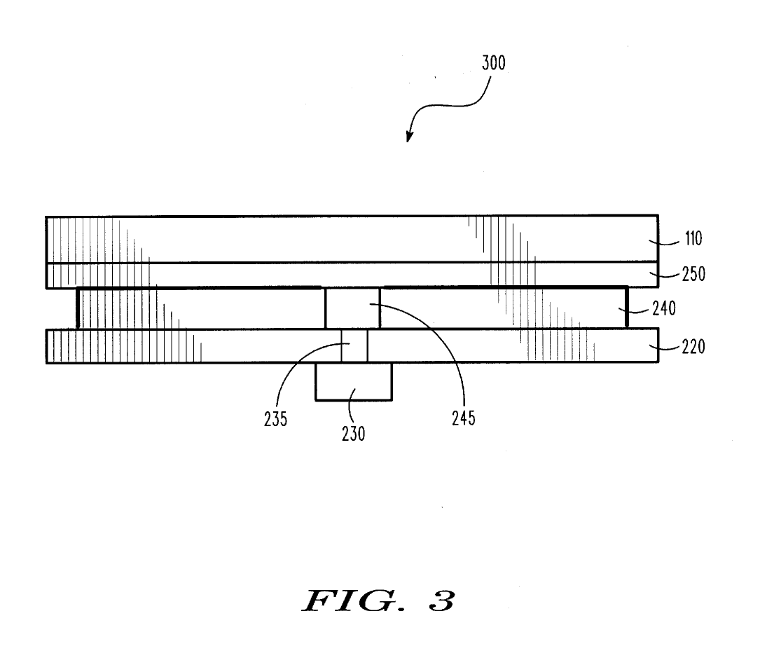

FIG. 3 shows a block diagram 300 of a system including a heat sink 110 and a thermal interface material 250, in a general-purpose handheld mobile computing device, such as the MU 150, according to the exemplary embodiments of the present invention. As shown in FIG. 3, the exemplary MU 150 may include a heat sink 110 (or alternatively, a housing 105), a radio component 220, which may be a printed circuit board (“PCB”), and a heat source (e.g., a heat generating component), such as the electronic parts 230 on RFID radio component 220. Furthermore, the PCB 220 may incorporate any number of thermal vias 235 connected to the MU's ground for transferring the heat from the source 230 to the heat sink 110. Those skilled in the art would understand that vias 235 may refer to any through-hole paths from one surface of the PCB 230 to the other surface.

As illustrated in FIG. 3, the hottest components of the RFID radio 220 (e.g., the electronic parts 230) may be located on the interior surface of the PCB 220 (i.e., the surface facing opposite the housing 110). As described above, the PCB 220 may include thermal vias 235, thereby allowing the heat to be transferred through the PCB 220. Specifically, a shield 240 may reside between PCB 220 and the heat sink 110. This metal shield 240 may include at least one metal slug 245 positioned over or near at least one of the vias 235. Therefore, the metal slug 245 may provide a thermal connection between the RFID radio component 220 and the thermal interface material 250, which is thermally connected to the heat sink 110. In another embodiment, the metal slug 245 is a separate part from shield 240 and still provides the thermal connection between the RFID radio component 220 and the thermal interface material 250. The exemplary systems and methods of transferring the heat to the heat sink 110 is more effective than attempting to transfer heat through a casing of the heat generating component (e.g., such as a casing of an RFID radio electronic part 230).

As described above, an alternative embodiment of the MU 150 may allow for the metal housing 105 of the MU 150 to act as the heat sink. Accordingly, the metal housing 105 may be composed of a thermally conductive material. Furthermore, the metal housing may be in direct thermal contact with the metal slug 245. It should be noted that if the housing 105 was composed of a non-metallic material (e.g., a plastic), the thermal design may not be as efficient since the thermal conductivity of non-metals are typically of a smaller order than that of metals.

The exemplary heat sink 110 may be manufactured from a variety of different thermal conducting materials, as well as a combination of one or more thermal conducting materials. The ability for the heat sink 110 to transfer heat may be related to the selection of material for the heat sink 110. Thermal conductivity may be defined as the property of a material that indicates its ability to conduct heat. Furthermore, thermal conductivity is measured in W/mK (Watts per meters-Kelvin), wherein a higher value means better thermal conductivity. The thermal conductivity of a material, such as a metal, depends on many properties of a material (e.g., its structure). As a general rule, materials with a high electrical conductivity tend to also have a high thermal conductivity. Furthermore, the heat sink 110 may be manufactured using any number of methods, including, but not limited to, extrusion, die-casting, cold forging, milling, bonding, folding, etc.

Aluminum has a relatively high magnitude of thermal conductivity, specifically on the order of 235 W/mK. Aluminum is also very light, thus an aluminum heat sink 110 will put less stress on the MU 150 when it is operating. Due to the softness of aluminum, aluminum may also be milled quickly and die-casting and cold forging may also be possible. In addition, an aluminum heat sink 110 may be manufactured using extrusion. Finally, the production of an aluminum heat sink 110 may be relatively inexpensive.

Copper has an even higher magnitude of thermal conductivity, specifically on the order of 400 W/mK. Accordingly, this makes it an excellent material for the heat sink 110. However, its disadvantages include high weight and price.

As described above, the advantages of aluminum and copper materials may be combined to create a heat sink 110 made of both aluminum and copper bonded together. For example, the area in contact with the heat generating component (e.g., the RFID electronic parts 230) may be made of copper. Accordingly, this may help lead the heat away to the outer parts of the heat sink 110. In addition, a copper embedding may be tightly bonded to an aluminum part in order to allow for good thermal transfer. If the thermal transfer between the copper and the aluminum is poor, the copper/aluminum heat sink 110 may not function properly.

Finally, it should be noted that the heat sink 110 may also be manufactured from silver. Silver has an even higher thermal conductivity than copper, specifically on the order of 430 W/mK. However, this increase does not justify the much higher price for heat sink production. As will be described below, pulverized silver may be a common ingredient in high-end thermal compounds. It should be noted that while the exemplary heat sink 110 is described as including aluminum, copper, and/or silver, the heat sink 110 may be manufactured from any thermally conductive material capable of transferring heat away from a heat generating component, such as the RFID radio electronic parts 230, towards the housing 105 of the MU 150.

According to one exemplary embodiment of the present invention, a thermal compound 250 may be placed between the heat sink 110 and the heat generating components 230. For example, if the surface of the heat sink 110 is not entirely flat, there may be small gaps under the heat sink 110. In addition, since air is a poor thermal conductor, these gaps have a very negative effect on the heat transfer. Therefore, an interface material 250 with a higher thermal conductivity than air may be implemented to fill these gaps, thereby improving heat conductivity between heat sink 110 and the heat generating components 230. This interface material may be the thermal compound, such as a thermal paste, a thermal pad, a thermal tape, thermal grease, etc. The material within these thermal compounds may include metal-based additives, such as zinc oxide, aluminum oxide, nitride, pulverized silver, as well as some non-metallic additives, such as silicone.

It will be apparent to those skilled in the art that various modifications may be made in the present invention, without departing from the spirit or the scope of the invention. Thus, it is intended that the present invention cover modifications and variations of this invention provided they come within the scope of the appended claimed and their equivalents.

What is claimed is:

1. A device, comprising:
a heat generating component; and
a heat sink in thermal contact with the heat generating component, the heat sink including at least one thermally conductive material.

2. The device according to claim 1, wherein the heat sink is electrically connected to a ground of the device.

3. The device according to claim 1, wherein the heat generating component is at least one radio component transmitting and receiving data.

4. The device according to claim 1, wherein the heat sink is manufactured from one or more of an aluminum material, a copper material, and a silver material.

5. The device according to claim 1, wherein the heat sink includes a plurality of cooling fins.

6. The device according to claim 5, wherein the thermal contact includes one of direct contact and radiant contact.

7. The device according to claim 1, wherein the heat sink substantially surrounds the heat generating component.

8. The device according to claim 1, further comprising:
a circuit on which the heat generating component is located, the circuit board including at least one thermal vias; and
at least one metallic slug located one of within and adjacent to the at least one thermal vias, the metallic slug transferring heat from the heat generating component to the heat sink.

9. The device according to claim 8, further comprising:
a thermal compound placed between the heat sink and the at least one metallic slug, the thermal compound conducting heat from the heat generating component to the heat sink.

10. The device according to claim 1, wherein the heat sink is a housing of the device.

11. The device according to claim 1, wherein the heat sink is located exterior to a housing of the device.

12. A system, comprising:
a mobile computing device including a heat generating component; and
a heat sink in thermal contact with the heat generating component, the heat sink including at least one thermally conductive material.

13. The system according to claim 12, wherein the heat sink is electrically connected to a ground of the device

14. The system according to claim 12, wherein the heat generating component is at least one radio component transmitting and receiving data.

15. The system according to claim 12, wherein the heat sink further includes a plurality of cooling fins.

16. The system according to claim 12, wherein the heat sink substantially surrounds the heat generating component.

17. The system according to claim 12, wherein the mobile computing device further includes a circuit board located between the heat sink and the heat generating component, the circuit board including at least one thermal vias, and at least one metallic slug located one of within and adjacent to the at least one thermal vias, the metallic slug transferring heat from the heat generating component to the heat sink.

18. The system according to claim 17, further comprising:
a thermal compound placed between the heat sink and the at least one metallic slug, the thermal compound conducting heat from the heat generating component to the heat sink.

19. The system according to claim 12, wherein the heat sink is a housing of the mobile computing device.

20. The system according to claim 12, wherein the heat sink is located exterior to a housing of the mobile computing device.

21. A device, comprising:
at least one radio transmission means for transmitting and receiving data from at least one target over a radio frequency; and
a heat transferring means in thermal contact with the at least one radio, the heat transferring means including at least one thermally conductive material.

22. The device according to claim 21, further comprising:
a cooling fins means for improving the thermal conductivity of the heat transferring means.
